(19) United States
(12) Patent Application Publication
(10) Pub. No.: US 2025/0317127 A1
(43) Pub. Date: Oct. 9, 2025

(54) APPARATUS FOR CORRECTING DUTY-CYCLE AND PHASE ERRORS OF QUADRATURE SIGNALS AND METHOD THEREFOR

(71) Applicant: KOREA ADVANCED INSTITUTE OF SCIENCE AND TECHNOLOGY, Daejeon (KR)

(72) Inventors: SeongHwan CHO, Daejeon (KR); Jaewon OH, Daejeon (KR)

(73) Assignee: KOREA ADVANCED INSTITUTE OF SCIENCE AND TECHNOLOGY, Daejeon (KR)

(21) Appl. No.: 19/172,837

(22) Filed: Apr. 8, 2025

(30) Foreign Application Priority Data
Apr. 9, 2024 (KR) 10-2024-0047929

(51) Int. Cl. H03K 3/017; H03F 3/45; H03K 19/20

(52) U.S. Cl. CPC H03K 3/017; H03F 3/45475; H03K 19/20

(57) ABSTRACT

An apparatus for correcting duty-cycle and phase errors of quadrature signals, which is capable of simultaneously detecting a quadrature error and a duty cycle error of the quadrature signals at one observation point and correcting the quadrature error and the duty cycle error, and a method therefor are disclosed. The apparatus for correcting duty-cycle and phase errors of quadrature signals according to an embodiment of the present disclosure includes a quadrature signal error detector configured to detect errors of quadrature signals including an I signal, which is an in-phase signal, and a Q signal, which is a quadrature phase signal; and a quadrature signal error compensator configured to compensate for duty cycles and phases of the quadrature signals depending on the errors of the quadrature signals.

### CROSS-REFERENCE TO RELATED APPLICATION

This application claims the benefit of and priority to Korean Patent Application No. 10-2024-0047929, filed on Apr. 9, 2024, the entire disclosure(s) of which is hereby incorporated herein by reference in its entirety.

### STATEMENT REGARDI_{N},G GOVERNMENT SPONSORED RESEARCH OR DEVELOPMENT

This work was supported by Institute of Information & communications Technology Planning & Evaluation (IITP) grant funded by the Korea government (MSIT). (No. 2023-00262634, An Ultra-low Power On-chip Training AI Semiconductor for Keyword Spotting) Meanwhile, in all the aspects of the inventive concept, there is no property interest in the government of the Republic of Korea.

### TECHNICAL FIELD

The present disclosure relates to an apparatus for correcting duty-cycle and phase errors of quadrature signals including an I signal, which is an in-phase signal, and a Q signal, which is a quadrature phase signal, and an method therefor.

### RELATED ART

There is a method of increasing an operating frequency of an IC chip as a scheme for increasing an IC processing rate or a data transmission speed, but increasing the operating frequency of the IC chip has problems in many aspects, such as increasing power consumption and generating heat. Therefore, a communication scheme for generating a quadrature signal of a 4-phase signal with the same spacing using a signal at the same frequency is widely used.

Quadrature signals include an I signal, which is an in-phase signal corresponding to a real axis, and a Q signal, which is a quadrature phase signal corresponding to an imaginary axis. When a spacing phase difference or duty cycle between the I and Q signals of the quadrature signals is not the same, a data error rate of an IC chip may increase, and thus, a circuit that corrects a spacing between the quadrature signals to be the same is required. Quadrature signal correction circuits of the related art assume that there is no duty cycle error of input quadrature signals of the correction circuit. However, when there is a duty cycle error of the quadrature signals, a quadrature error proportional to the duty cycle error may be observed at an output of the correction circuit. In such a case, a duty cycle error correction circuit for correcting the duty cycle error of the quadrature signals and a quadrature error correction circuit for correcting a phase of the quadrature signal are required to be used together.

It is preferred that a quadrature and duty cycle error correction circuit satisfy requirements of accuracy, background operability, low power, small area, and wide bandwidth. Accuracy performance is important because the accuracy performance is closely related to errors and noise. The background operability is an indicator of robust operation performance against environmental factors, such as temperature inside a chip, process variables, or the like. Low-power performance is important because the low-power performance has a great influence on a data processing rate per unit area, a heat generation issue, power costs, and the like. Wideband performance is important because the wideband performance enables a reduction of circuit design costs, and various modes of operation inside a chip.

A quadrature and duty cycle error correction circuit of the related art has been designed solely as a circuit that corrects a duty cycle error of signals or a circuit that corrects a quadrature error. However, there is a problem that, as described above, in the quadrature error correction circuit that actually receives a signal with a duty cycle error as an input, a quadrature error or a duty cycle error inevitably appears in an output in proportion to the input duty cycle error. When the duty cycle error is corrected first and then the quadrature error is corrected, the duty cycle error may be corrupted again during the correction of the quadrature error, which may cause a problem in the accuracy of fundamental quadrature signal correction. Further, since separate circuits are configured for duty cycle error correction and quadrature error correction, additional circuit area and power may be required. In addition, when the duty cycle error and the quadrature error are ascertained by respective error detectors at one observation point and corrected, an error in quadrature signal correction may be caused by a collision between correction circuits, and an additional circuit area and power may be required because respective error detectors are required for duty cycle correction and phase correction.

### SUMMARY

An object of the present disclosure is to provide an apparatus for correcting duty-cycle and phase errors of quadrature signals, which is capable of simultaneously detecting the quadrature error and the duty cycle error of quadrature signals at one observation point and correcting the quadrature error and the duty cycle error, and a method therefor.

Another object of the present disclosure is to provide an apparatus for correcting duty-cycle and phase errors of quadrature signals, which is capable of efficiently correcting a quadrature error and a duty cycle error of the quadrature signals while preventing a collision between a quadrature error correction circuit and a duty cycle error correction circuit, and a method therefor.

Still another object of the present disclosure is to provide an apparatus for correcting duty-cycle and phase errors of quadrature signals, which is capable of reducing a circuit area and power for detecting a quadrature error and a duty cycle error of quadrature signals using a single error detector and correcting the quadrature error and the duty cycle error, and a method therefor.

Still another object of the present disclosure is to provide an apparatus for correcting duty-cycle and phase errors of quadrature signals, which has a wide operating frequency range (wideband characteristics) and is capable of operating even at high frequencies, and a method therefor.

Objects of the present disclosure are not limited to the objects as described above, and other objects can be inferred from embodiments below.

An apparatus for correcting duty-cycle and phase errors of quadrature signals according to an aspect of the present disclosure includes a quadrature signal error detector configured to detect errors related to duty-cycles and phases of quadrature signals including an I signal, which is an in-phase signal, and a Q signal, which is a quadrature phase signal; and a quadrature signal error compensator configured to compensate for the duty cycles and phases of the quadrature signals depending on the errors of the quadrature signals. The quadrature signal error detector is configured to perform a NAND operation or an AND operation on the quadrature signals to detect the errors of the quadrature signals.

The quadrature signal error detector may include a plurality of NAND operators configured to perform a NAND operation on an I signal, a Q signal, an inverted signal of the I signal, and an inverted signal of the Q signal; and a low pass filter unit configured to perform low pass filtering on output signals of the plurality of NAND operators and output error detection signals.

The quadrature signal error compensator may include an error amplifier configured to generate at least one of a phase error compensation signal for amplifying an error of the error detection signals with respect to a reference signal and adjusting a time delay of the quadrature signals and a duty cycle error compensation signal for adjusting bias voltages of the quadrature signals.

The quadrature signal error compensator may be configured to adjust at least one of a delay time and a bias voltage of the quadrature signals depending on at least one of the phase error compensation signal and the duty cycle error compensation signal.

The error amplifier may include a phase error amplification unit configured to amplify the phase error of the quadrature signals based on the error detection signals of the quadrature signals; and a bias error amplification unit configured to amplify a bias error of the quadrature signals based on the error detection signals of the quadrature signals.

A frequency bandwidth of the phase error amplification unit may be set to be higher than that of the bias error amplification unit.

The phase error amplification unit may include a phase error amplifier configured to amplify a phase error of at least two of the error detection signals with respect to the reference signal to generate phase error amplification signals for the I signal and the Q signal; and a phase error low pass filter unit configured to generate phase error compensation signals for adjusting phases of the quadrature signals by performing low passing on the phase error amplification signals.

The bias error amplification unit may include a bias error amplifier configured to amplify bias errors for at least two of the error detection signals with respect to the reference signal to generate bias error amplification signals for the I signal and the Q signal; and a bias error low pass filter unit configured to generate duty cycle error compensation signals for adjusting bias voltages of quadrature signals by performing low passing on the bias error amplification signals.

The quadrature signal error compensator may include a phase adjuster configured to adjust phases of the quadrature signals depending on an error of the error detection signals with respect to the reference signal; and a duty cycle adjuster configured to adjust a bias voltage of the quadrature signals depending on an error of the error detection signals with respect to the reference signal.

The quadrature signal error detector may include a first NAND operator configured to perform a NAND operation on the I signal and the Q signal; a second NAND operator configured to perform a NAND operation on the I signal and an inverted Q signal that is an inverted signal of the Q signal; a third NAND operator configured to perform a NAND operation on an inverted I signal which is an inverted signal of the I signal, and the Q signal; and a fourth NAND operator configured to perform a NAND operation on the inverted I signal and the inverted Q signal.

A method for correcting duty-cycle and phase errors of quadrature signals according to an aspect of the present disclosure includes detecting, by a quadrature signal error detector, errors of quadrature signals including an I signal, which is an in-phase signal, and a Q signal, which is a quadrature phase signal; and compensating for, by a quadrature signal error compensator, duty cycles and phases of the quadrature signals depending on the errors of the quadrature signals.

The detecting of the errors of the quadrature signals includes performing a NAND operation or an AND operation on the quadrature signals to detect the errors of the quadrature signals.

Further, according to an aspect of the present disclosure, there is provided a computer-readable non-transitory recording medium having recorded thereon a computer program for executing the method of correcting duty-cycle and phase errors of quadrature signals.

According to the aspect of the present disclosure, there is provided an apparatus for correcting duty-cycle and phase errors of quadrature signals, which is capable of simultaneously detecting a quadrature error and a duty cycle error of the quadrature signals at one observation point and correcting the quadrature error and the duty cycle error, and a method therefor.

Further, according to the aspect of the present disclosure, it is possible to correct the quadrature error and the duty cycle error of the quadrature signals while preventing collision between the quadrature error correction circuit and the duty cycle error correction circuit.

Further, according to the aspect of the present disclosure, it is possible to reduce a circuit area and power for correction of the quadrature error and the duty cycle error by detecting the quadrature error and the duty cycle error of the quadrature signals using a single error detector.

Further, according to the aspect of the present disclosure, it is possible to provide an apparatus for correcting duty-cycle and phase errors of quadrature signals that have a wide operating frequency range (wideband characteristics) and are capable of operating at high frequencies, and a method therefor.

### BRIEF DESCRIPTION OF THE DRAWI_{N},GS

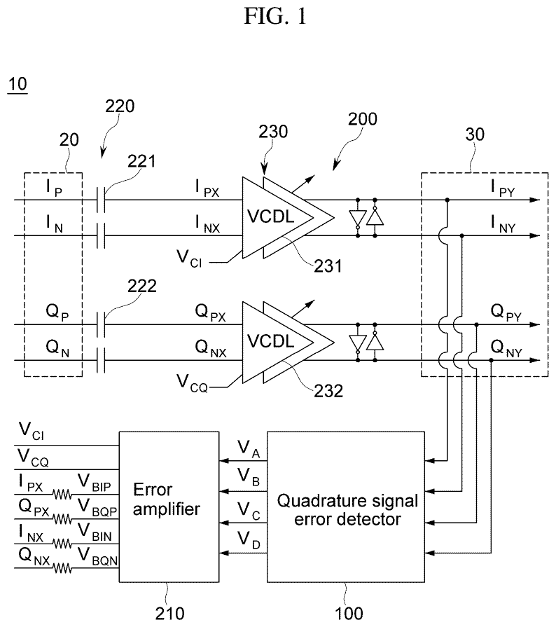

FIG. 1 is a configuration diagram illustrating an apparatus for correcting duty-cycle and phase errors of quadrature signals according to an embodiment of the present disclosure.

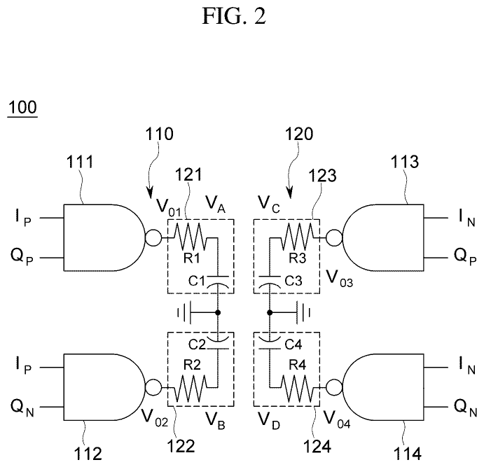

FIG. 2 is a configuration diagram illustrating a quadrature signal error detector of the apparatus for correcting duty-cycle and phase errors of quadrature signals according to the embodiment of the present disclosure.

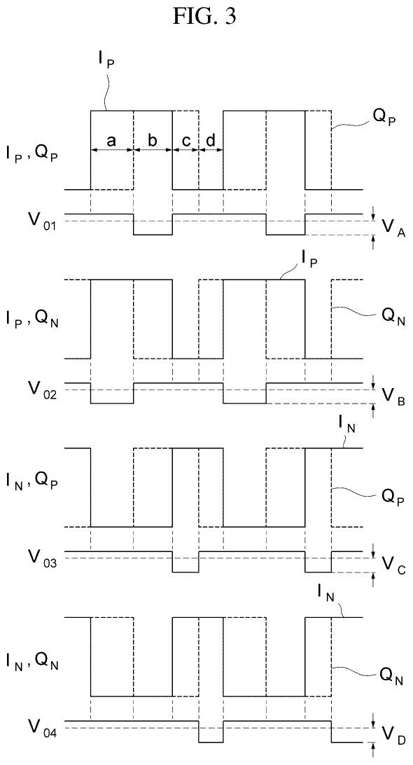

FIG. 3 is a signal diagram of quadrature signals illustrating an operation of the quadrature signal error detector of the apparatus for correcting duty-cycle and phase errors of quadrature signals according to the embodiment of the present disclosure.

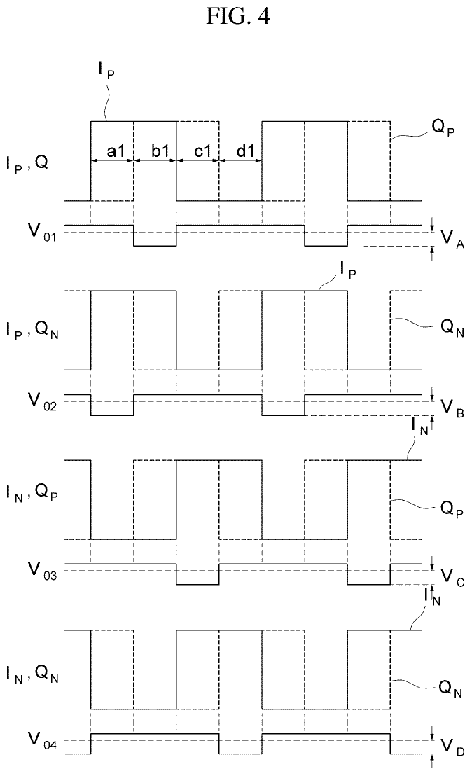

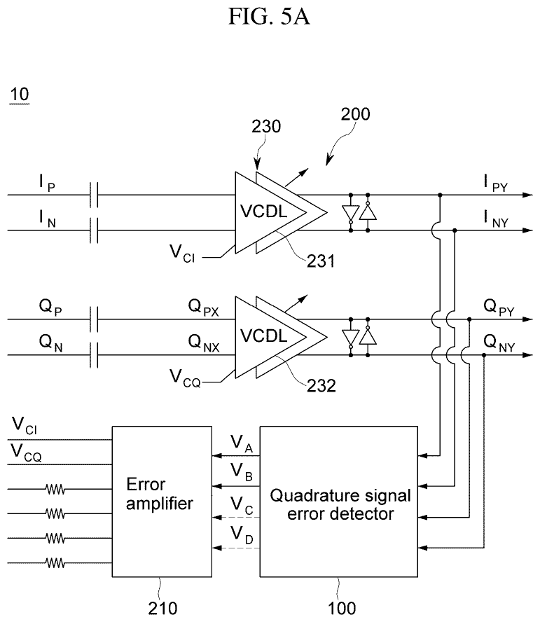

FIG. 4 is a diagram illustrating quadrature signals that are corrected by the apparatus for correcting duty-cycle and phase errors of quadrature signals according to the embodiment of the present disclosure.

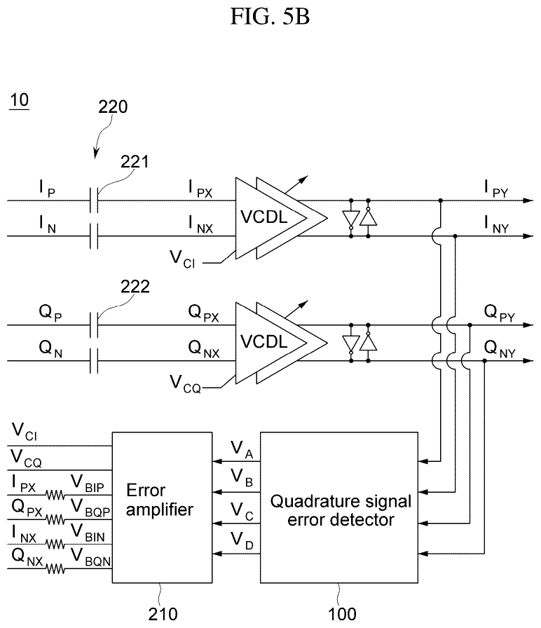

FIG. 5A is a diagram illustrating a phase correction operation in the apparatus for correcting duty-cycle and phase errors of quadrature signals according to the embodiment of the present disclosure.

FIG. 5B is a diagram illustrating a duty cycle correction operation in the apparatus for correcting duty-cycle and phase errors of quadrature signals according to the embodiment of the present disclosure.

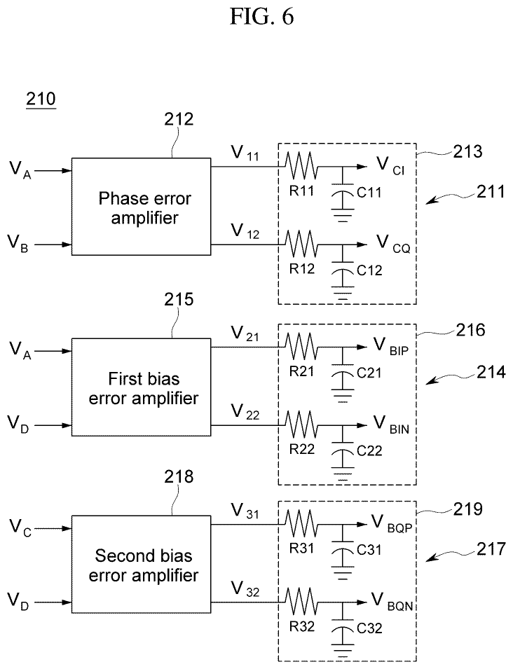

FIG. 6 is a configuration diagram of an error amplifier in the apparatus for correcting duty-cycle and phase errors of quadrature signals according to the embodiment of the present disclosure.

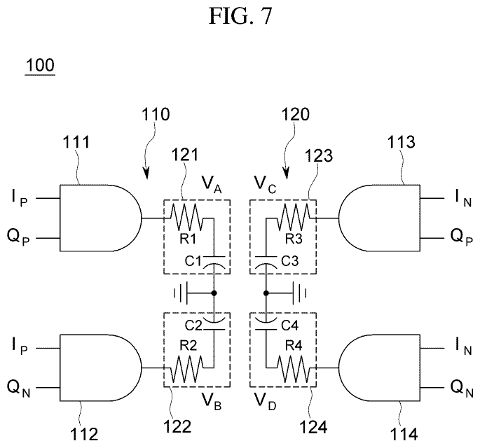

FIG. 7 is a block diagram illustrating a quadrature signal error detector of an apparatus for correcting duty-cycle and phase errors of quadrature signals according to another embodiment of the present disclosure.

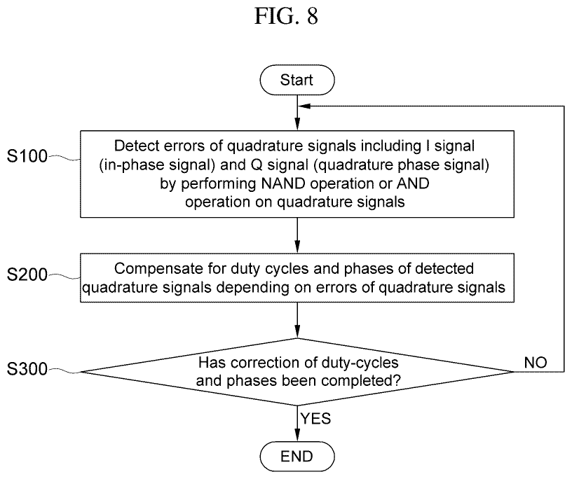

FIG. 8 is a flowchart of a method of correcting duty-cycle and phase errors of quadrature signals according to an embodiment of the present disclosure.

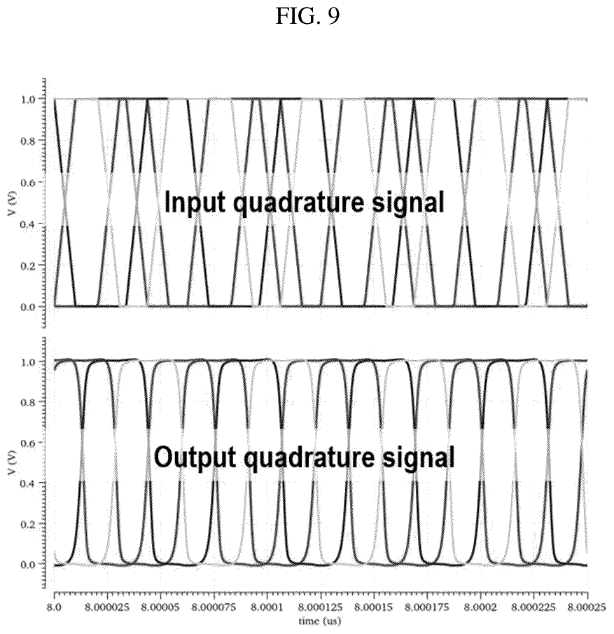

FIGS. 9 to 14 are simulation results illustrating performance of the apparatus for correcting duty-cycle and phase errors of quadrature signals according to the embodiment of the present disclosure, which are results of correcting a duty cycle and phase of a 16 GHz quadrature signal.

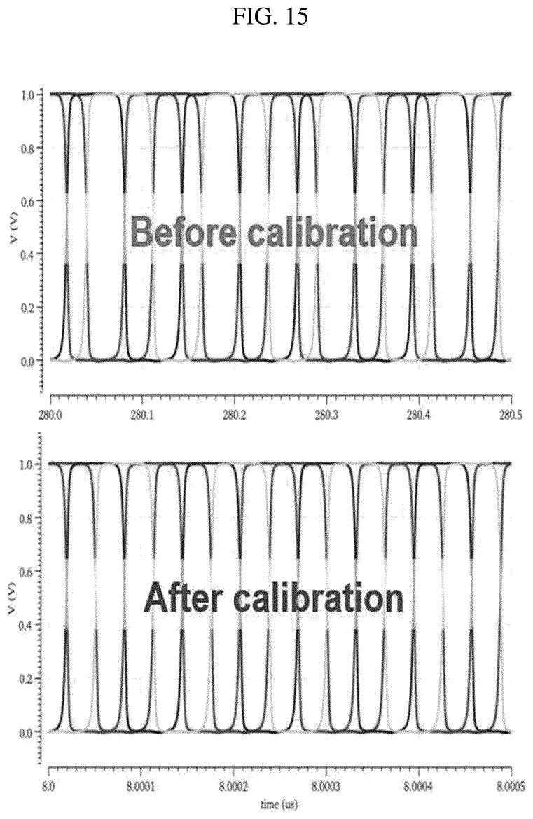

FIGS. 15 to 20 illustrate simulation results showing the performance of the apparatus for correcting duty-cycle and phase errors of quadrature signals according to the embodiment of the present disclosure, which are results of correcting a duty cycle and phase of an 8 GHz quadrature signal.

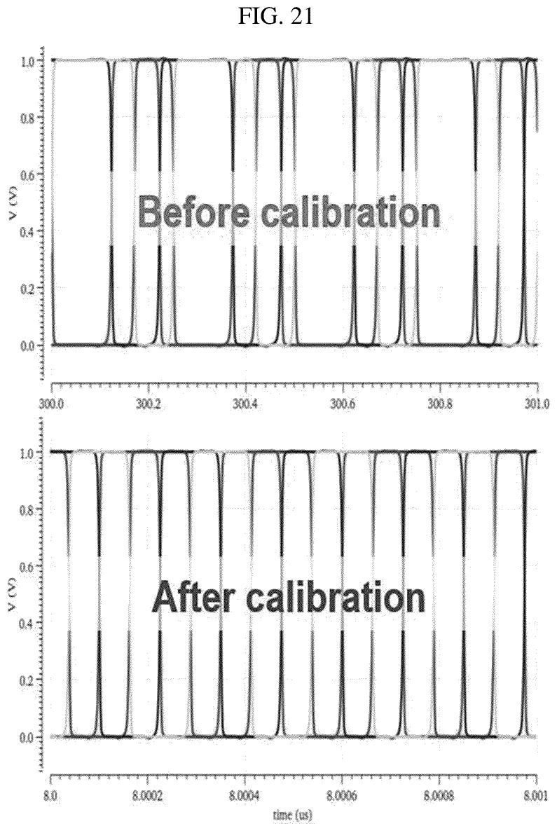

FIGS. 21 to 26 are diagrams illustrating simulation results showing the performance of the apparatus for correcting duty-cycle and phase errors of quadrature signals according to the embodiment of the present disclosure, which are results of correcting a duty cycle and phase of the 4 GHz quadrature signal.

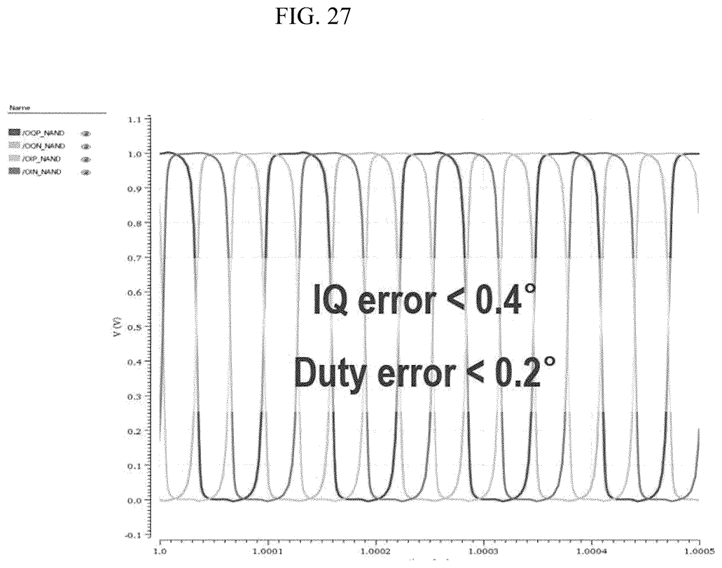

FIGS. 27 to 30 are diagrams illustrating results of correcting the duty cycle and phase of the 8 GHz quadrature signal under the worst simulation conditions at high temperature of 100° C.

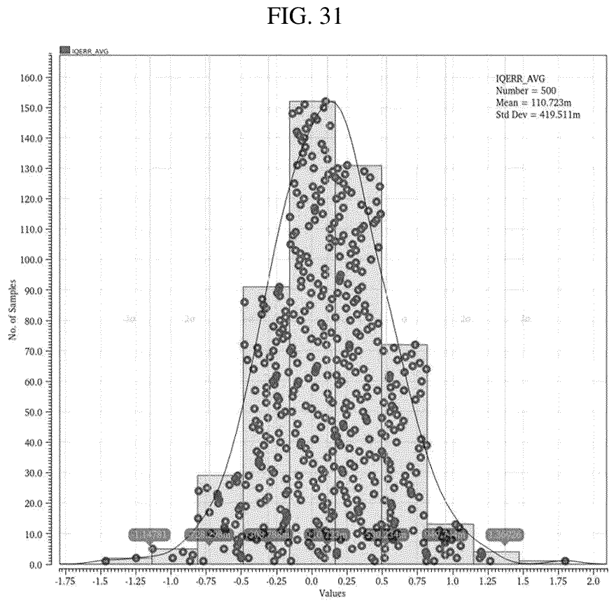

FIG. 31 illustrates results of simulating a phase error distribution for the 8 GHz quadrature signal according to Monte Carlo simulation in an embodiment of the present disclosure.

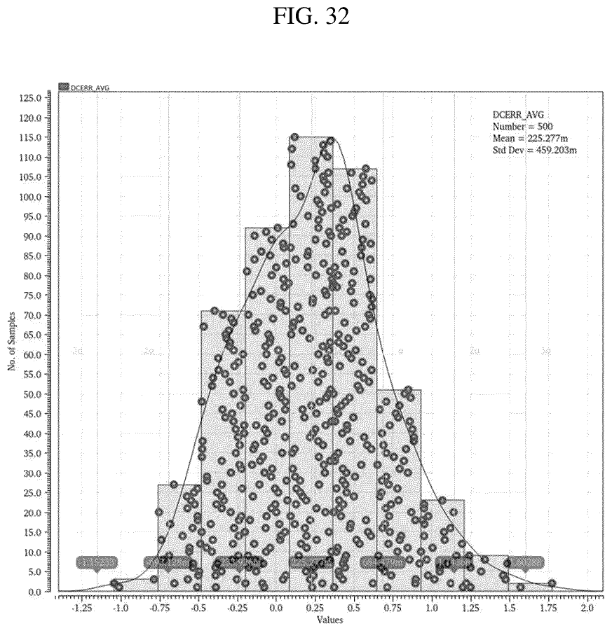

FIG. 32 illustrates results of simulating a duty cycle error distribution for the 8 GHz quadrature signal according to Monte Carlo simulation in an embodiment of the present disclosure.

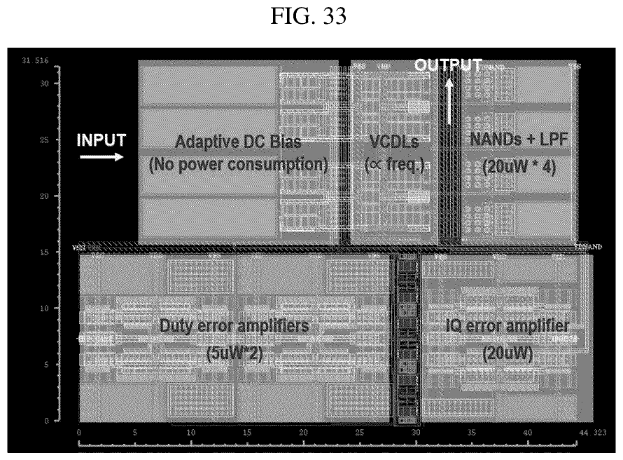

FIG. 33 is a diagram illustrating a design layout of the apparatus for correcting duty-cycle and phase errors of quadrature signals according to the embodiment of the present disclosure.

### DETAILED DESCRIPTION OF EMBODIMENTS

Hereinafter, embodiments of the present disclosure will be described in detail with reference to the accompanying drawings so that those skilled in the art can easily implement the present disclosure. The present disclosure may be implemented in various different forms and is not limited to the embodiments that will be described herein. It should be noted that the drawings are schematic and not drawn to scale. Relative dimensions and ratios of parts in the drawings are exaggerated or reduced in size for clarity and convenience in the drawings, and any dimensions are merely exemplary and not limiting. The same reference signs are used to indicate similar features for the same structures, elements, or parts that appear in two or more drawings.

The embodiments of the present disclosure specifically illustrate ideal embodiments of the present disclosure. As a result, various modifications of the drawings are expected. Therefore, the embodiments are not limited to a specific form of an illustrated area, and include modifications of forms due to manufacturing, for example. All technical and scientific terms used herein have the meanings commonly understood by those skilled in the art to which the present disclosure pertains unless otherwise defined. All terms used herein are selected for the purpose of more clearly describing the present disclosure and are not selected to limit the scope of the rights according to the present disclosure.

Expressions such as “including”, “comprising,” and “having” used herein should be understood as open-ended terms that imply the possibility of including other embodiments, unless otherwise stated in phrases or sentences in which the expression is included. Singular expressions described herein may include a plural meaning unless otherwise stated, and this also applies to singular expressions described in the claims. Expressions such as “first” and “second,” used herein are used to distinguish between a plurality of components and do not limit an order or importance of the components.

A “˜module” and “˜unit” used herein may mean a unit that processes at least one function or operation, for example, a hardware component such as software, an FPGA, or one or more processors. When it is determined that detailed description of a related known function or configuration may unnecessarily obscure the gist of the present disclosure in describing embodiments of the present disclosure, the detailed description may be omitted.

FIG. 1 is a configuration diagram illustrating an apparatus for correcting duty-cycle and phase errors of quadrature signals according to an embodiment of the present disclosure. Referring to FIG. 1, an apparatus for correcting duty-cycle and phase errors of quadrature signals 10 according to an embodiment of the present disclosure may operate to simultaneously correct duty-cycle and phase errors of quadrature signals including an I signal, which is an in-phase signal corresponding to a real axis, and a Q signal, which is a quadrature phase signal corresponding to an imaginary axis.

As is well known in the technical field of the present disclosure, the I signal may be an I channel signal corresponding to a real axis of an original signal, and the Q signal may be a Q channel signal corresponding to an imaginary axis of the original signal. A scheme for converting the original signal into a quadrature signal and processing data is advantageous in processing or transmitting data without increasing an operating frequency of an IC chip. Since data processing and transmission technology based on a quadrature signal is well known in the technical field of the present disclosure, detailed description thereof will be omitted.

In order to correct the duty-cycle and phase errors of the quadrature signals, the apparatus for correcting duty-cycle and phase errors of quadrature signals 10 according to the embodiment of the present disclosure may include a quadrature signal error detector 100 and a quadrature signal error compensator 200. The quadrature signal error detector 100 may detect a duty cycle error and quadrature error of quadrature signals including I signals I_{P} and I_{N} which are in-phase signals, and Q signals Q_{P} and Q_{N} which are quadrature phase signals. For example, the I signal may be the signal I_{P} that is obtained by multiplying the original signal by a cosine function and then performing low pass filtering on a resultant signal, and the Q signal may be a signal Q_{P} obtained by multiplying the original signal by a sine function and performing low pass filtering on a resultant signal, but the present disclosure is not necessarily limited thereto.

The quadrature signal error detector 100 may perform a NAND operation or an AND operation on the quadrature signals I_{P}, I_{N}, Q_{P}, and Q_{N} to detect errors of the quadrature signals. A detailed configuration and circuit structure of the quadrature signal error detector 100 that performs the NAND operation or the AND operation to detect the errors of the quadrature signals will be described later with reference to FIG. 2. The quadrature signal error detector 100 may output error detection signals V_{A}, V_{B}, V_{C}, and V_{D} related to errors of the quadrature signals I_{P}, I_{N}, Q_{P}, and Q_{N} or I_{PY}, I_{NY}, Q_{PY}, and Q_{NY}. The error detection signals V_{A}, V_{B}, V_{C}, and V_{D} generated by the quadrature signal error detector 100 may be input to the quadrature signal error compensator 200 for duty-cycle and phase correction of the quadrature signals.

The quadrature signal error compensator 200 may compensate for duty cycles and phases of quadrature signals 20 (I_{P}, I_{N}, Q_{P}, and Q_{N}) depending on duty cycle and quadrature errors of the quadrature signals to output duty cycle and phase-corrected quadrature signals 30 (I_{PY}, I_{NY}, Q_{PY}, and Q_{NY}). The quadrature signal error compensator 200 may adjust at least one of a phase (delay time) and a bias voltage of the quadrature signals I_{P}, I_{N}, Q_{P}, and Q_{N} depending on errors of the error detection signals V_{A}, V_{B}, V_{C}, and V_{D} with respect to a reference signal (for example, a set reference voltage) output by the quadrature signal error detector 100. The quadrature signal error compensator 200 may include an error amplifier 210, a duty cycle adjuster 220, and a phase adjuster 230.

The error amplifier 210 may amplify the errors of the error detection signals V_{A}, V_{B}, V_{C}, and V_{D} of the quadrature signals with respect to a reference signal. The reference signal may be a preset reference voltage (for example, 0.75 V), but is not necessarily limited thereto. A reference signal for at least one of the error detection signals V_{A}, V_{B}, V_{C}, and V_{D} may be set with another error detection signal as a reference.

The error amplifier 210 may amplify the errors of the error detection signals V_{A}, V_{B}, V_{C}, and V_{D} output from the quadrature signal error detector 100 with respect to the reference signal based on the I signal, the Q signal, the inverted signal of the I signal, and the inverted signal of the Q signal (or the phase-corrected quadrature signals). The error amplifier 210 may output phase error compensation signals V_{CI} and V_{CQ} for adjusting the phases of the quadrature signals and duty cycle error compensation signals V_{BIP}, V_{BQP}, V_{BIN}, and V_{BQN} for adjusting the duty cycles of the quadrature signals based on the error detection signals V_{A}, V_{B}, V_{C}, and V_{D}.

The duty cycle adjuster 220 may adjust the bias voltages of the quadrature signals I_{P}, I_{N}, Q_{P}, and Q_{N} through negative feedback depending on the errors of the error detection signals V_{A}, V_{B}, V_{C}, and V_{D} of the quadrature signals with respect to the reference signal to correct the duty cycles of the quadrature signals I_{P}, I_{N}, Q_{P}, and Q_{N}. The duty cycle adjuster 220 may adjust the bias voltages of the quadrature signals I_{P}, I_{N}, Q_{P}, and Q_{N} to output bias-adjusted quadrature signals I_{PX}, I_{NX}, Q_{PX}, and Q_{NX}. For the duty cycle adjuster 220, various duty cycle adjustment circuits that perform a function of adjusting a duty cycle of a signal using a bias voltage may be used. Since the duty cycle adjustment circuit is well known in the technical field of the present disclosure, detailed description thereof will be omitted.

In the embodiment of FIG. 1, the duty cycle adjuster 220 includes a first duty cycle adjuster 221 and a second duty cycle adjuster 222. The first duty cycle adjuster 221 may adjust the duty cycles through bias voltage adjustment of the I signal I_{P} and the inverted I signal I_{N} (or a phase-adjusted I signal and a phase-adjusted inverted I signal) to output a duty cycle-corrected I signal I_{PX} and a duty cycle-corrected inverted I signal I_{NX}. The second duty cycle adjuster 222 may adjust the duty cycles through the bias voltage adjustment of the Q signal Q_{P} and the inverted Q signal Q_{N} (or a phase-adjusted Q signal and a phase-adjusted inverted Q signal to output a duty cycle-corrected Q signal Q_{PX} and a duty cycle-corrected inverted Q signal Q_{NX}.

The phase adjuster 230 may adjust the bias voltages of the quadrature signals I_{P}, I_{N}, Q_{P}, and Q_{N} or the duty cycle-corrected quadrature signals I_{PX}, I_{NX}, Q_{PX}, and Q_{NX} to output phase-adjusted quadrature signals I_{PY}, I_{NY}, Q_{PY}, and Q_{NT}. The phase adjuster 230 may adjust a phase (delay time) of the quadrature signals I_{P}, I_{N}, Q_{P}, and Q_{N} or the duty cycle-corrected quadrature signals I_{PX}, I_{NX}, Q_{PX}, and Q_{NX} through negative feedback depending on the errors of the error detection signals V_{A}, V_{B}, V_{C}, and V_{D} with reference to the reference signal. In one embodiment, the phase adjuster 230 may be implemented as voltage controlled delay lines (VCDLs) 231 and 232, but is not necessarily limited thereto and any device may be used as long as the device can adjust the phase of the quadrature signal.

In the embodiment of FIG. 1, the phase adjuster 230 includes a first voltage controlled delay line 231 and a second voltage controlled delay line 232. The first voltage controlled delay line 231 may adjust the delay time of the I signal I_{P} and the inverted I signal I_{N} or the bias-adjusted I signal I_{PX} and the inverted I signal I_{NX} to output a phase-corrected I signal I_{PY} and a phase-corrected inverted I signal I_{NY}. The second voltage controlled delay line 232 may adjust the delay time of the Q signal Q_{P} and the inverted Q signal Q_{N} or the bias-adjusted Q signal Q_{PX} and the inverted Q signal Q_{NX} to output a phase-corrected Q signal Q_{PY} and a phase-corrected inverted Q signal Q_{NY}.

In the illustrated example, the duty cycle is corrected through the adjustment of the bias voltages of the quadrature signals I_{P}, I_{N}, Q_{P}, and Q_{N}, and then the phase is corrected, but the duty cycle correction and the phase correction may be performed in reverse, or the duty-cycle correction and the phase correction may be performed simultaneously. Duty cycle and quadrature errors of the quadrature signals I_{PY}, I_{NY}, Q_{PY}, and Q_{NY} whose duty-cycle and phase have been corrected by the duty cycle adjuster 220 and the phase adjuster 230 are detected by the quadrature signal error detector 100 again, and thus, the duty cycle and phase error correction may be repeatedly performed again. This process may be repeated until the duty-cycle and phase errors of the corrected quadrature signals I_{PY}, I_{NY}, Q_{PY}, and Q_{NY} become less than a reference error.

FIG. 2 is a configuration diagram illustrating the quadrature signal error detector of the apparatus for correcting duty-cycle and phase errors of quadrature signals according to the embodiment of the present disclosure. Referring to FIGS. 1 and 2, the quadrature signal error detector 100 may include a NAND operation unit 110 including a plurality of NAND operators (NAND gates) 111, 112, 113, and 114, and a low pass filter unit 120 including a plurality of low pass filters 121, 122, 123, and 124. The plurality of NAND operators 111, 112, 113, and 114 of the NAND operation unit 110 may perform a NAND operation on an I signal I_{P} or I_{PY}, a Q signal Q_{P} or Q_{PY}, an inverted I signal I_{N} or I_{NY} which is an inverted signal of the I signal, and an inverted Q signal Q_{N} or Q_{NY} which is an inverted signal of the Q signal.

The low pass filter unit 120 may perform low pass filtering on output signals V₀₁, V₀₂, V₀₃, and V₀₄ of the plurality of NAND operators 111, 112, 113, and 114 to output the error detection signals V_{A}, V_{B}, V_{C}, and V_{D}. In an embodiment, the respective low pass filters 121, 122, 123, and 124 may include resistors R1, R2, R3, and R4 connected in series with output terminals of NAND operators 111, 112, 113, and 114, and capacitors C1, C2, C3, and C4 connected between the resistors R1, R2, R3, and R4 and ground, but the low pass filter is not limited to a connection structure of the resistors and capacitors as illustrated, and may be replaced with other element structures capable of performing a low pass function.

In an embodiment, the NAND operation unit 110 may include a first NAND operator 111, a second NAND operator 112, a third NAND operator 113, and a fourth NAND operator 114. The first NAND operator 111 may perform a NAND operation on the I signal I_{P} or I_{PY} and the Q signal Q_{P} or Q_{PY}. The second NAND operator 112 may perform a NAND operation on the I signal I_{P} or I_{PY} and the inverted Q signal Q_{N} or Q_{NY}, which is an inverted signal of the Q signal. The third NAND operator 113 may perform a NAND operation on the inverted I signal I_{N} or I_{NY}, which is an inverted signal of the I signal, and the Q signal Q_{P} or Q_{PY}. The fourth NAND operator 114 may perform a NAND operation on the inverted I signal I_{N} or I_{NY} and the inverted Q signal Q_{N} or Q_{NY}. In the illustrated embodiment, the error detection signals V_{A}, V_{B}, V_{C}, and V_{D} of quadrature signals are output through error detection signal output terminals between the resistors R1, R2, R3, and R4 and the capacitors C1, C2, C3, and C4 of the low pass filter unit 120 and are input to the error amplifier 210 of the quadrature signal error compensator 200.

FIG. 3 is a signal diagram of quadrature signals illustrating an operation of the quadrature signal error detector of the apparatus for correcting duty-cycle and phase errors of quadrature signals according to the embodiment of the present disclosure. Ideally, among the quadrature signals, the I signal IP and the Q signal Q_{P} have a phase difference of 90° and the same duty. The apparatus for correcting duty-cycle and phase errors of quadrature signals 10 can correct the quadrature signal so that the I signal I_{P} and the Q signal Q_{P} have an ideal phase and duty cycle.

In the example of FIG. 3, the apparatus for correcting duty-cycle and phase errors of quadrature signals 10 may correct the duty cycles and phases of the quadrature signals so that spacings of the quadrature signals (a spacing ‘a’ between a rising edge of the I signal and a rising edge of the Q signal, a spacing ‘b’ between the rising edge of the Q signal and a falling edge of the I signal, a spacing ‘c’ between the falling edge of the I signal and a falling edge of the Q signal, and a spacing ‘d’ between the falling edge of the Q signal and the rising edge of the I signal) become all the same.

The quadrature signal error detector 100 may be configured to perform a NAND operation on the quadrature signals to simultaneously detect phases and duty cycles of the I signal I_{P} and the Q signal Q_{P} with a small area and low power. The error detection signals V_{A}, V_{B}, V_{C}, and V_{D} detected by the quadrature signal error detector 100 may be output to the quadrature signal error compensator 200. The quadrature signal error compensator 200 may correct the duty cycles and phases of the quadrature signals so that the error detection signals V_{A}, V_{B}, V_{C}, and V_{D} detected by the quadrature signal error detector 100 all have the same value.

The first NAND output signal V₀₁ output from the first NAND operator 111 of the quadrature signal error detector 100 has a rising edge at the falling edge of the I signal and a falling edge at the rising edge of the Q signal. Since the first NAND output signal V₀₁ is subjected to low pass processing in the first low pass filter 121 of the quadrature signal error detector 100, a first error detection signal V_{A} corresponding to an average value of the first NAND output signal V₀₁ is output through an output terminal of the first low pass filter 121. The first error detection signal V_{A} is output in proportion to a magnitude of a sum of values in sections a, c, and d of FIG. 3.

The second NAND output signal V₀₂ output from the second NAND operator 112 of the quadrature signal error detector 100 has a rising edge at a falling edge of the inverted Q signal, and a falling edge at the rising edge of the I signal. Since the second NAND output signal V₀₂ is subjected to low pass processing in the second low pass filter 122 of the quadrature signal error detector 100, a second error detection signal V_{B} corresponding to an average value of the second NAND output signal V₀₂ is output through an output terminal of the second low pass filter 122. The second error detection signal V_{B} is output in proportion to a magnitude of a sum of values in sections b, c, and d of FIG. 3.

The third NAND output signal V₀₃ output from the third NAND operator 113 of the quadrature signal error detector 100 has a rising edge at the falling edge of the Q signal and a falling edge at a rising edge of the inverted I signal. Since the third NAND output signal V₀₃ is subjected to low pass processing in the third low pass filter 123 of the quadrature signal error detector 100, a third error detection signal V_{C} corresponding to an average value of the third NAND output signal V₀₃ is output through an output terminal of the third low pass filter 123. The third error detection signal V_{C} is output in proportion to a magnitude of a sum of the values in the sections a, b, and d of FIG. 3.

The fourth NAND output signal V₀₄ output from the fourth NAND operator 114 of the quadrature signal error detector 100 has a rising edge at a falling edge of the inverted I signal and a falling edge at a rising edge of the inverted Q signal. Since the fourth NAND output signal V₀₄ is subjected to low pass processing in the fourth low pass filter 124 of the quadrature signal error detector 100, a fourth error detection signal V_{D} corresponding to an average value of the fourth NAND output signal V₀₄ is output through an output terminal of the fourth low pass filter 124. The fourth error detection signal V_{D} is output in proportion to a magnitude of a sum of the values in the sections a, b, and c of FIG. 3.

FIG. 4 is a diagram illustrating quadrature signals that are corrected by the apparatus for correcting duty-cycle and phase errors of quadrature signals according to the embodiment of the present disclosure. When a process of correcting the phases and duty cycles of the quadrature signals in the quadrature signal error detector 100 and the quadrature signal error compensator 200 is repeated, the quadrature signals whose phases and duty cycles have been corrected include I and Q signals with a phase difference of 90° and the same duty cycle, as illustrated in FIG. 4. That is, the phases and duty cycles of the quadrature signals are corrected so that spacings a1, b1, c1, and d1 between adjacent rising and falling edges of the I signal and the Q signal of the quadrature signal all have the same value.

That is, when the quadrature signal error detector 100 includes NAND operators, phase and duty cycle correction for the quadrature signals may be performed until values of the error detection signals V_{A}, V_{B}, V_{C}, and V_{D} generated by the quadrature signal error detector 100 become 0.75 times a maximum output value (maximum output voltage) of the NAND output signals V₀₁, V₀₂, V₀₃, and V04. For example, when the maximum output voltage of the NAND output signals V₀₁, V₀₂, V₀₃, and V₀₄ is 1 V, the phase and duty cycle correction for the quadrature signals is performed until all the error detection signals V_{A}, V_{B}, V_{C}, and V_{D} become 0.75 V.

FIG. 5A is a diagram illustrating a phase correction operation in the apparatus for correcting duty-cycle and phase errors of quadrature signals according to the embodiment of the present disclosure. FIG. 5B is a diagram illustrating a duty cycle correction operation in the apparatus for correcting duty-cycle and phase errors of quadrature signals according to the embodiment of the present disclosure. FIG. 6 is a configuration diagram of an error amplifier in the apparatus for correcting duty-cycle and phase errors of quadrature signals according to the embodiment of the present disclosure.

Referring to FIG. 6, the error amplifier 210 may include a phase error amplification unit 211 and bias error amplification units 214 and 217. The phase error amplification unit 211 may amplify the phase error of the quadrature signals based on the error detection signals. The bias error amplification units 214 and 217 may amplify the bias error of quadrature signals based on the quadrature signals.

The phase error amplification unit 211 may include a phase error amplifier 212 and a phase error low pass filter 213. The phase error amplifier 212 can amplify at least two or more (for example, V_{A} and V_{B}) of the error detection signals to amplify a phase error of the I signal and the Q signal. The phase error low pass filter 213 may perform low passing on error amplification signals V₁₁ and V₁₂ amplified and output by the phase error amplifier 212 to output phase error compensation signals V_{CI} and V_{CQ} for phase error correction of quadrature signals.

The bias error amplification units 214 and 217 may include a first bias error amplification unit 214 and a second bias error amplification unit 217. The first bias error amplification unit 214 may include a first bias error amplifier 215 and a first bias error low pass filter unit 216. The second bias error amplification unit 217 may include a second bias error amplifier 218 and a second bias error low pass filter unit 219.

The first bias error amplifier 215 and the second bias error amplifier 218 may amplify at least two or more (for example, V_{A}, V_{C}, and V_{D}) of the error detection signals to amplify a bias error of the I signal and the Q signal. The first bias error low pass filter unit 216 and the second bias error low pass filter unit 219 may perform low passing on the bias error amplification signals V₂₁, V₂₂, V₃₁, and V₃₂ amplified and output by the first bias error amplifier 215 and the second bias error amplifier 218 to output the duty cycle error compensation signals V_{BIP}, V_{BQP}, V_{BIN}, and V_{BQN} for adjusting the bias voltages of the quadrature signals.

In the embodiment, the phase error low pass filter and the bias error low pass filter may include resistors R₁₁, R₁₂, R₂₁, R₂₂, R₃₁, and R₃₂ connected in series with output terminals of the phase error amplifier and the bias error amplifier, and capacitors C₁₁, C₁₂, C₂₁, C₂₂, C₃₁, and C₃₂ connected between the resistors R₁₁, R₁₂, R₂₁, R₂₂, R₃₁, and R₃₂ and the ground, but the low pass filter is not limited to a connection structure of the resistors and the capacitors as illustrated, and may be replaced with other element structures capable of performing a low pass function.

A phase error detection frequency bandwidth of the error amplifier 210 for phase correction in the phase adjuster 230 may be set to be higher than a bias error detection frequency bandwidth of the error amplifier 210 for the duty cycle correction in the duty cycle adjuster 220. The phase error detection frequency bandwidth and the bias error detection frequency bandwidth can be defined by resistance and capacitance values of the phase error low pass filter and the bias error low pass filter.

In one embodiment, in order to set the phase error detection frequency bandwidth to be higher than the bias error detection frequency bandwidth, values of the resistors R₁₁ and R₁₂ of the phase error low pass filter may be set to be smaller than those of the resistors R₂₁, R₂₂, R₃₁, and R₃₂ of the bias error low pass filter. For example, the values of the resistors R₂₁, R₂₂, R₃₁, and R₃₂ of the bias error low pass filter may be designed to be at least twice the values of the resistors R₁₁ and R₁₂ of the phase error low pass filter.

Thus, a bandwidth for phase adjustment in the phase adjuster 230 is set to be much higher than a duty cycle correction bandwidth through the bias voltage adjustment in the duty cycle adjuster 220, making it possible to prevent collision between feedback loops of the phase adjuster 230 and the duty cycle adjuster 220. This prevention of the collision between the feedback loops for phase correction and duty cycle correction for the quadrature signals makes it possible to efficiently correct the phase and the duty cycle of the quadrature signals without a feedback loop collision problem.

The apparatus for correcting duty-cycle and phase errors of quadrature signals according to the embodiment of the present disclosure can correct the phase and duty cycle of quadrature signal to satisfy all requirements such as accuracy of the phase and duty cycle of the quadrature signal, background operability, low power, small area, and wide bandwidth. Accordingly, a data error and noise of the quadrature signals can be reduced, and operation can be robust to environmental factors such as temperature inside the chip, or process variables.

Further, with the apparatus for correcting duty-cycle and phase errors of quadrature signals according to the embodiment of the present disclosure, it is possible to improve a data processing rate per unit area due to small area and low power performance, and to correct the phases and duty cycles of the quadrature signals at a low power cost without a heat generation issue. In addition, since the apparatus has wideband performance, the apparatus has the advantage of reducing circuit design costs and operating in various modes inside a chip.

Further, the apparatus for correcting duty-cycle and phase errors of quadrature signals according to the embodiment of the present disclosure does not need to separately include a circuit for correcting the duty cycle error and a circuit for correcting the quadrature error, and can simultaneously correct the duty cycle and phase of the quadrature signal. Therefore, it is possible to accurately correct the phases and duty cycles of the quadrature signals without corrupting the duty cycle error due to the correction of the quadrature error or corrupting the quadrature error due to the correction of the duty cycle error, and to minimize a circuit area and power consumption while not causing an error in the quadrature signal correction due to a collision between the correction circuits. In addition, the quadrature signal error detector according to the embodiment of the present disclosure can operate at a high frequency and thus has the advantage of having a wide operating frequency range.

FIG. 7 is a block diagram illustrating a quadrature signal error detector of an apparatus for correcting duty-cycle and phase errors of quadrature signals according to another embodiment of the present disclosure. The quadrature signal error detector 100 according to the embodiment of FIG. 7 differs from that according to the above-described embodiment in that the quadrature signal error detector 100 is implemented by AND operators instead of the NAND operators. In the embodiment of FIG. 7, the quadrature signal error compensator 200 can correct the phases and duty cycles of the quadrature signals so that average values (for example, voltage averages) of error detection signals output by a plurality of AND operators of the quadrature signal error detector 100 become the same.

FIG. 8 is a flowchart of a method of correcting duty-cycle and phase errors of quadrature signals according to an embodiment of the present disclosure. Referring to FIGS. 1 and 8, the method of correcting duty-cycle and phase errors of quadrature signals according to an embodiment of the present disclosure may include a step S100 of detecting, by the quadrature signal error detector 100, errors of quadrature signals including an I signal and a Q signal by performing a NAND operation or an AND operation on the quadrature signals, and a step S200 of compensating for, by the quadrature signal error compensator 200, the duty cycles and phases of the quadrature signals depending on the errors of the quadrature signals. The processes S100 and S200 of correcting the duty-cycles and phases of the quadrature signals may be repeatedly performed until the duty cycles and phases of the quadrature signals satisfy set ideal conditions (S300).

FIGS. 9 to 14 are simulation results illustrating performance of the apparatus for correcting duty-cycle and phase errors of quadrature signals according to the embodiment of the present disclosure, which are results of correcting a duty cycle and phase of a 16 GHz quadrature signal. A signal (input quadrature signal) shown in an upper part of FIG. 9 is a 16 GHz quadrature signal before correction, and a signal (output quadrature signal) shown at a lower part of FIG. 9 is a 16 GHz quadrature signal after correction.

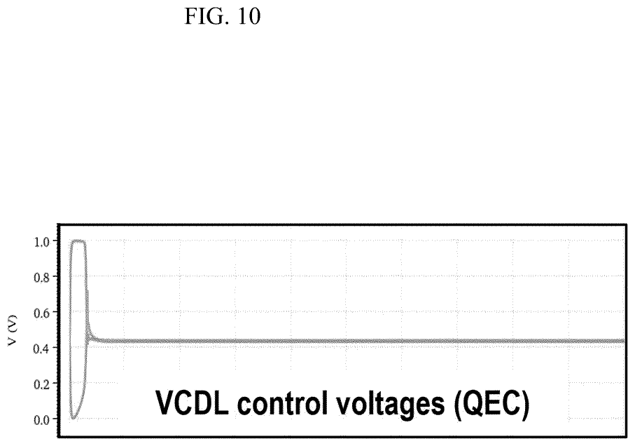

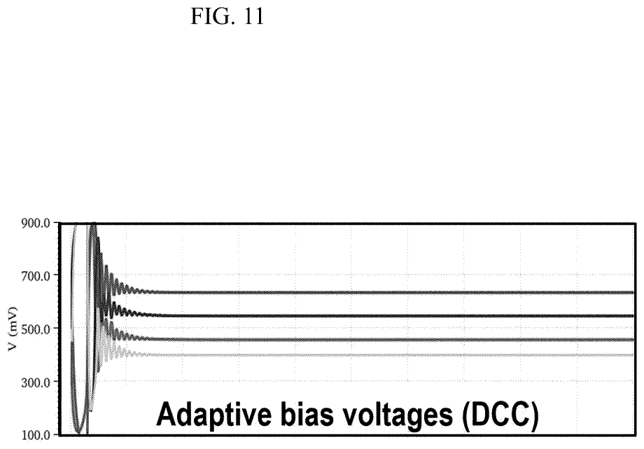

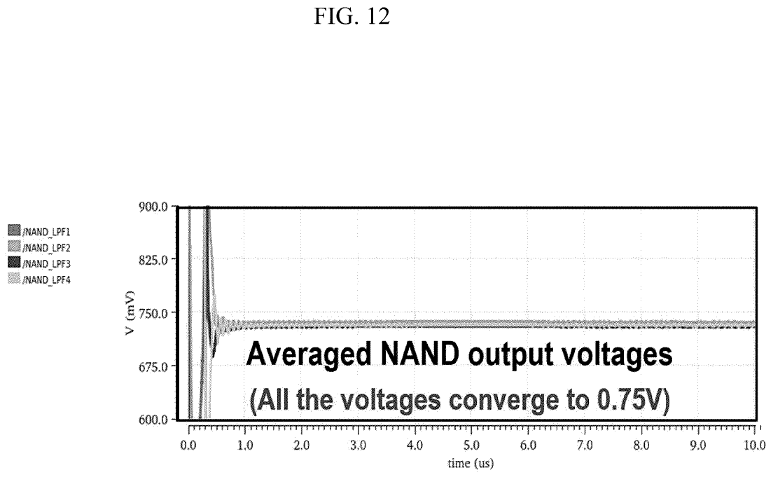

FIG. 10 is a diagram illustrating a phase control voltage of the voltage controlled delay line for phase correction for the 16 GHz quadrature signal in the apparatus for correcting duty-cycle and phase errors of quadrature signals according to the embodiment of the present disclosure. FIG. 11 is a diagram illustrating a bias voltage of a duty cycle corrector for duty cycle correction for the 16 GHz quadrature signal in the apparatus for correcting duty-cycle and phase errors of quadrature signals according to the embodiment of the present disclosure. FIG. 12 is a diagram illustrating an average output voltage of the NAND operators for duty-cycle and phase correction for the 16 GHz quadrature signal in the apparatus for correcting duty-cycle and phase errors of quadrature signals according to the embodiment of the present disclosure.

In FIG. 10, VCI_NAND and VCQ_NAND represent phase control voltages for phase correction for the I signal and the Q signal, respectively. In FIG. 11, VCIP_DCC, VCQP_DCC, VCIN_DCC, and VCQN_DCC represent bias voltages for duty cycle correction of the I signal, the Q signal, the inverted I signal, and the inverted Q signal, respectively. In FIG. 12, NAND_LPF1, NAND_LPF2, NAND_LPF3, and NAND_LPF4 represent output voltages of four NAND operators.

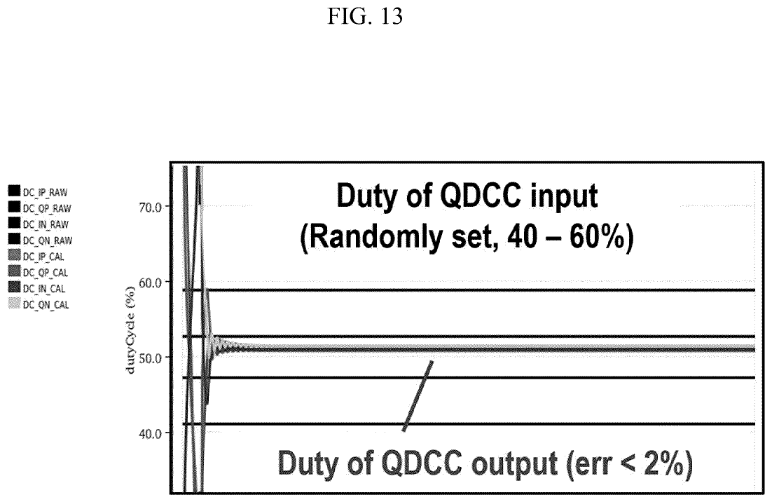

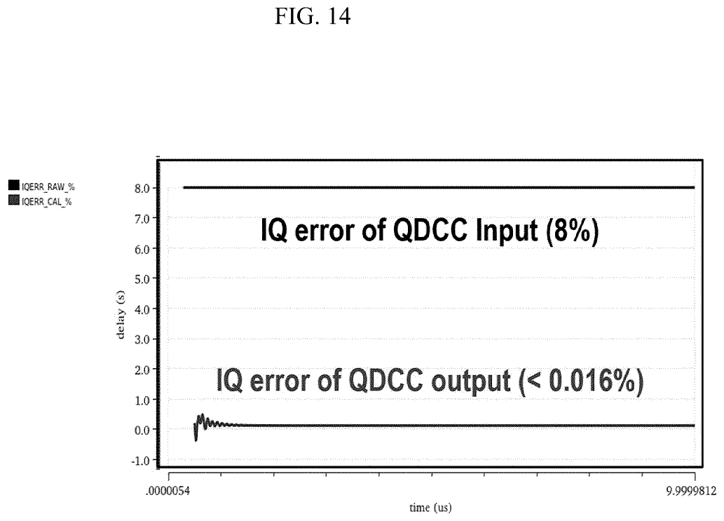

FIG. 13 is a diagram illustrating a change in duty cycle of the 16 GHz quadrature signal that is corrected by the apparatus for correcting duty-cycle and phase errors of quadrature signals according to the embodiment of the present disclosure. FIG. 14 is a diagram illustrating a change in phase of the 16 GHz quadrature signal that is corrected by the apparatus for correcting duty-cycle and phase errors of quadrature signals according to the embodiment of the present disclosure.

In FIG. 13, DC_IP_RAW, DC_QP_RAW, DC_IN_RAW, and DC_QN_RAW represent duty cycles before correction of the I signal, the Q signal, the inverted I signal, and the inverted Q signal, respectively, and DC_IP_CAL, DC_QP_CAL, DC_IN_CAL, and DC_QN_CAL represent corrected duty cycles of the I signal, the Q signal, the inverted I signal, and the inverted Q signal, respectively. In FIG. 14, IQERR_RAW_% represents a quadrature phase error before correction, and IQERR_CAL_% represents a quadrature phase error after correction.

It can be seen from FIGS. 9 to 14 that, with the apparatus for correcting duty-cycle and phase errors of quadrature signals according to the embodiment of the present disclosure, output voltages of the four NAND operators converge to the same voltage 0.75 V (see FIG. 12), and the duty cycle error can be reduced to less than 2% and the phase error can be reduced to less than 0.016% for the 16 GHz quadrature signal (see FIGS. 13 and 14).

FIGS. 15 to 20 illustrate simulation results showing the performance of the apparatus for correcting duty-cycle and phase errors of quadrature signals according to the embodiment of the present disclosure, which are results of correcting a duty cycle and phase of an 8 GHz quadrature signal. A signal (input quadrature signal) shown in an upper part of FIG. 15 is an 8 GHz quadrature signal before correction, and a signal (output quadrature signal) shown in a lower part of FIG. 15 is an 8 GHz quadrature signal after correction.

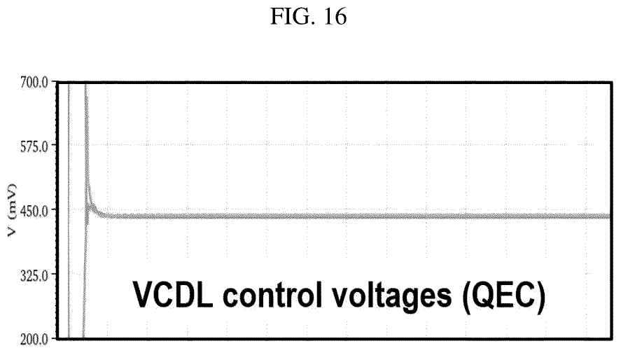

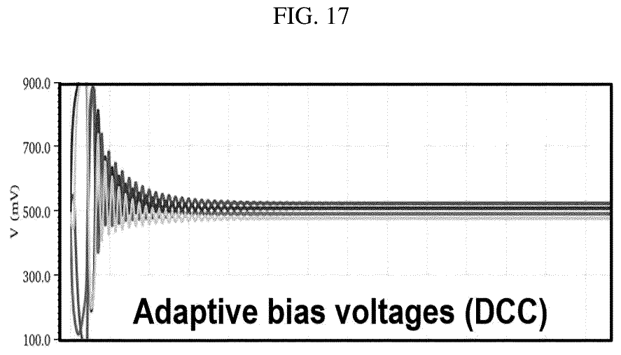

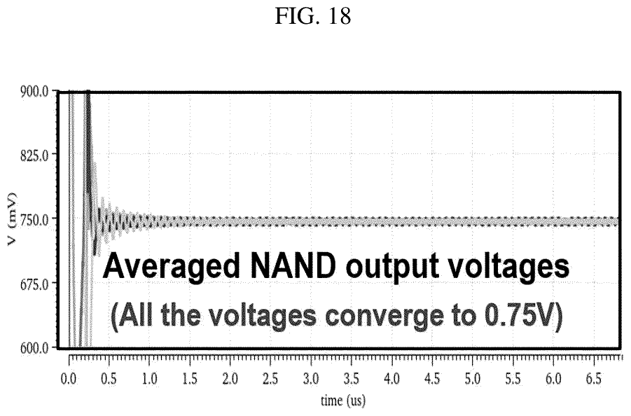

FIG. 16 is a diagram illustrating a phase control voltage of a voltage controlled delay line for phase correction for the 8 GHz quadrature signal in the apparatus for correcting duty-cycle and phase errors of quadrature signals according to the embodiment of the present disclosure. FIG. 17 is a diagram illustrating a bias voltage of a duty cycle corrector for duty cycle correction for the 8 GHz quadrature signal in the apparatus for correcting duty-cycle and phase errors of quadrature signals according to the embodiment of the present disclosure. FIG. 18 is a diagram illustrating an average output voltage of NAND operators for duty-cycle and phase correction for the 8 GHz quadrature signal in the apparatus for correcting duty-cycle and phase errors of the quadrature signals according to the embodiment of the present disclosure.

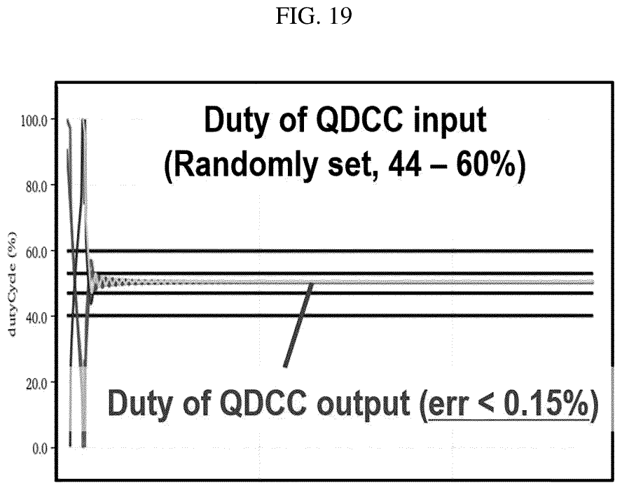

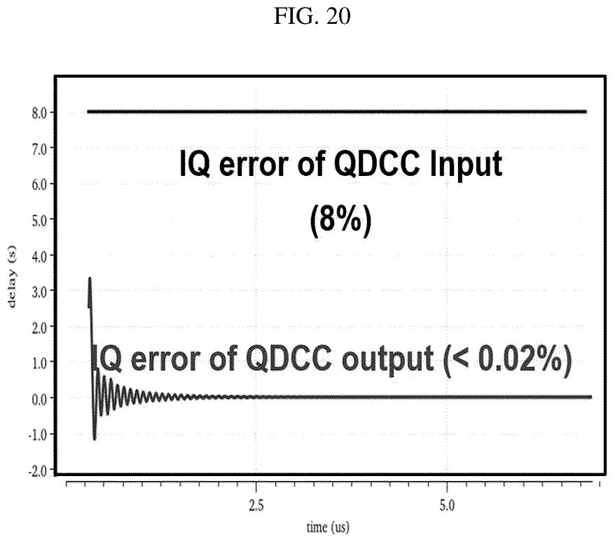

FIG. 19 is a diagram illustrating a change in duty cycle of the 8 GHz quadrature signal that is corrected by the apparatus for correcting duty-cycle and phase errors of quadrature signals according to the embodiment of the present disclosure. FIG. 20 is a diagram illustrating a change in phase of the 8 GHz quadrature signal that is corrected by the apparatus for correcting duty-cycle and phase errors of quadrature signals according to the embodiment of the present disclosure.

It can be seen from FIGS. 15 to 20 that, with the apparatus for correcting duty-cycle and phase errors of quadrature signals according to the embodiment of the present disclosure, output voltages of four NAND operators converge to the same voltage (0.75 V) (see FIG. 18), and the duty cycle error can be reduced to less than 0.15% and the phase error can be reduced to less than 0.02% for the 8 GHz quadrature signal (see FIGS. 19 and 20).

FIGS. 21 to 26 are diagrams illustrating simulation results showing the performance of the apparatus for correcting duty-cycle and phase errors of quadrature signals according to the embodiment of the present disclosure, which are results of correcting a duty cycle and phase of the 4 GHz quadrature signal. A signal (input quadrature signal) shown in an upper part of FIG. 21 is a 4 GHz quadrature signal before correction, and a signal (output quadrature signal) shown in a lower part of FIG. 21 is a 4 GHz quadrature signal after correction.

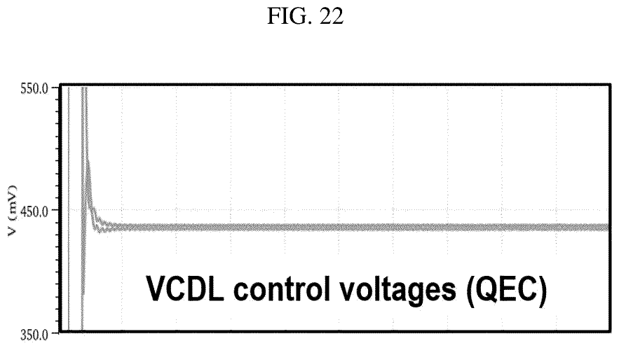

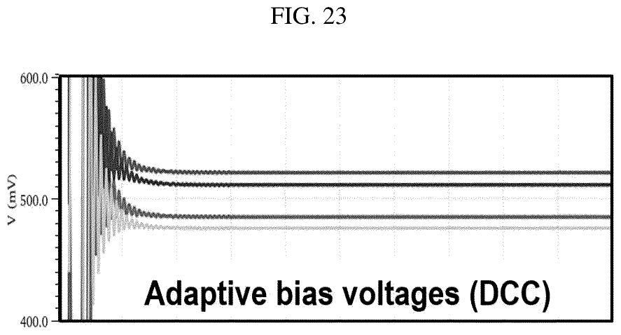

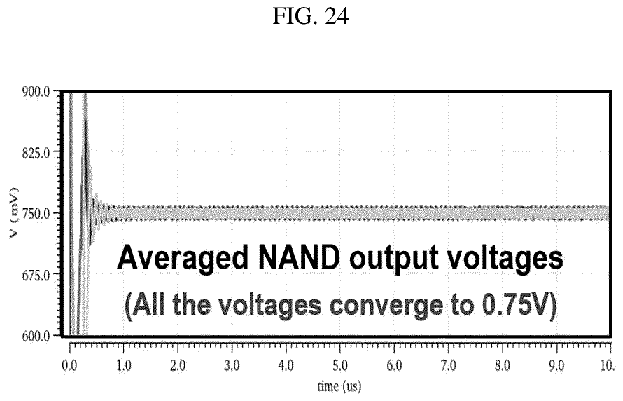

FIG. 22 is a diagram illustrating a phase control voltage of a voltage controlled delay line for phase correction for the 4 GHz quadrature signal in the apparatus for correcting duty-cycle and phase errors of quadrature signals according to the embodiment of the present disclosure. FIG. 23 is a diagram illustrating a bias voltage of a duty cycle corrector for duty cycle correction for the 4 GHz quadrature signal in the apparatus for correcting duty-cycle and phase errors of quadrature signals according to the embodiment of the present disclosure. FIG. 24 is a diagram illustrating an average output voltage of NAND operators for duty-cycle and phase correction of the 4 GHz quadrature signal in the apparatus for correcting duty-cycle and phase errors of quadrature signals according to the embodiment of the present disclosure.

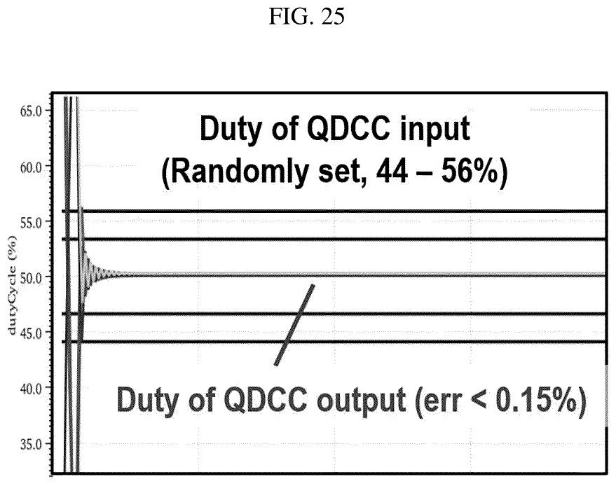

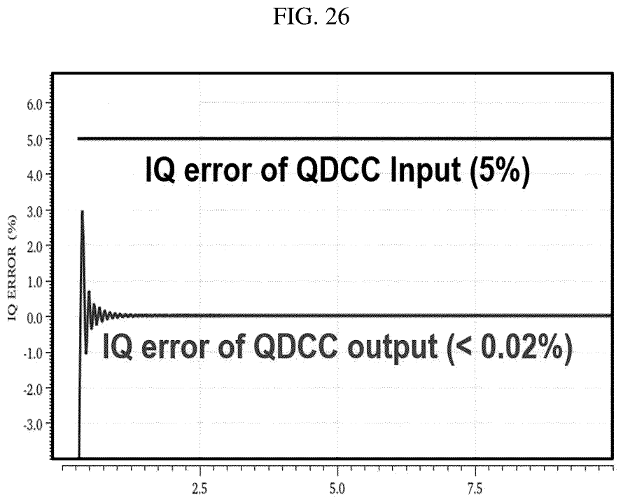

FIG. 25 is a diagram illustrating a change in duty cycle of the 4 GHz quadrature signal that is corrected by the apparatus for correcting duty-cycle and phase errors of quadrature signals according to the embodiment of the present disclosure. FIG. 26 is a diagram illustrating a change in phase of the 4 GHz quadrature signal that is corrected by the apparatus for correcting duty-cycle and phase errors of quadrature signals according to the embodiment of the present disclosure.

It can be seen from FIGS. 21 to 26 that, with the apparatus for correcting duty-cycle and phase errors of quadrature signals according to the embodiment of the present disclosure, the output voltages of the four NAND operators converge to the same voltage (0.75 V) (see FIG. 24), and the duty cycle error can be reduced to less than 0.15% and the phase error can be reduced to less than 0.02% for the 4 GHz quadrature signal (see FIGS. 25 and 26).

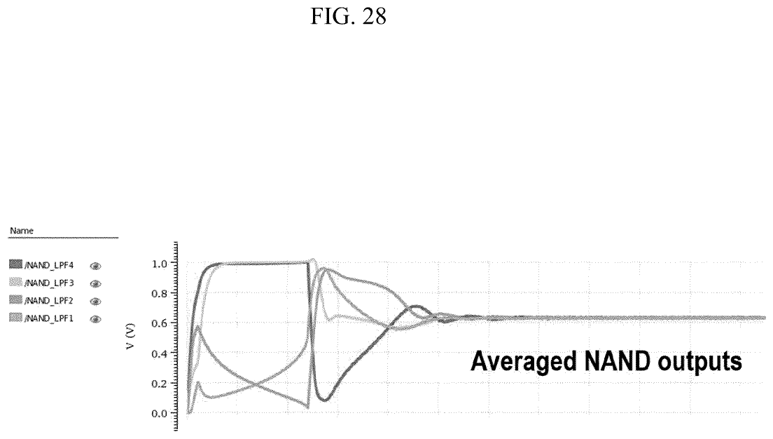

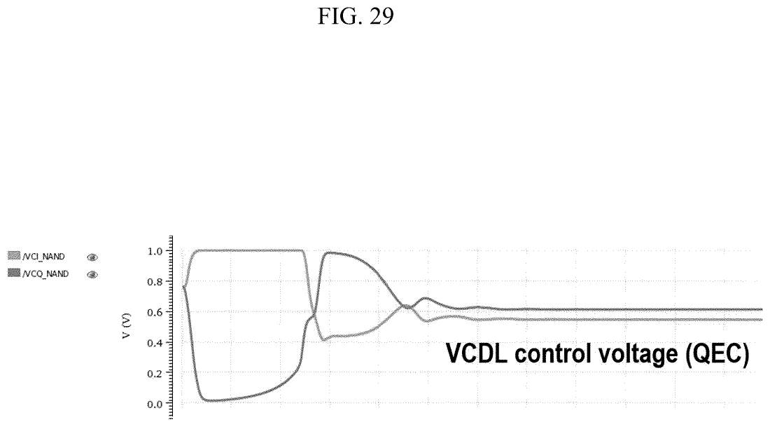

FIGS. 27 to 30 are diagrams illustrating results of correcting the duty cycle and phase of the 8 GHz quadrature signal under the worst simulation conditions at high temperature (100° C.). FIG. 27 is a diagram illustrating average output voltages of the NAND operators for duty-cycle and phase correction of the 8 GHz quadrature signal under the worst conditions in the apparatus for correcting duty-cycle and phase errors of quadrature signals according to the embodiment of the present disclosure. FIG. 28 is a diagram illustrating a phase control voltage of a voltage controlled delay line for phase correction for the 8 GHz quadrature signal under the worst condition in the apparatus for correcting duty-cycle and phase errors of quadrature signals according to the embodiment of the present disclosure. FIG. 29 is a diagram illustrating a bias voltage of a duty cycle corrector for duty cycle correction for the 8 GHz quadrature signal under the worst condition in the apparatus for correcting duty-cycle and phase errors of quadrature signals according to the embodiment of the present disclosure.

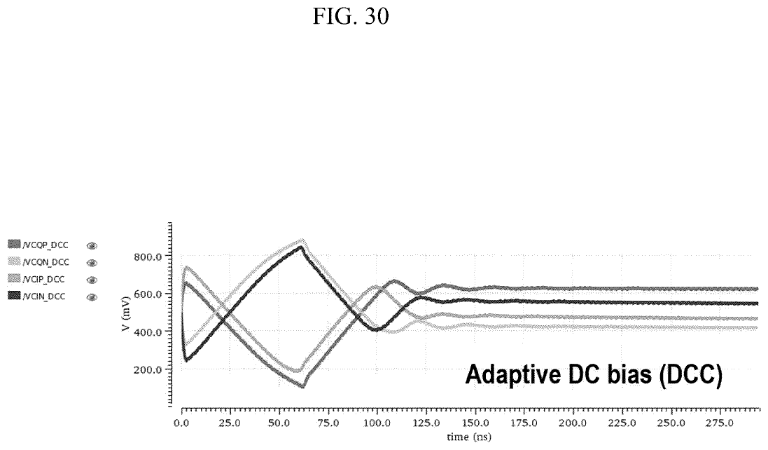

FIG. 30 illustrates the 8 GHz quadrature signal that is corrected according to an embodiment of the present disclosure. It can be seen from FIGS. 27 to 30 that, with the apparatus for correcting duty-cycle and phase errors of quadrature signals according to the embodiment of the present disclosure, a phase error of the 8 GHz quadrature signal can be corrected to be within 0.4° and a duty cycle error of the 8 GHz quadrature signal can be corrected to be within 0.2° even under harsh conditions such as a high temperature of 100° C. (see FIG. 30).

FIG. 31 illustrates results of simulating a phase error distribution for the 8 GHz quadrature signal according to Monte Carlo simulation in an embodiment of the present disclosure. FIG. 32 illustrates results of simulating a duty cycle error distribution for the 8 GHz quadrature signal according to Monte Carlo simulation in an embodiment of the present disclosure.

It can be seen from FIGS. 31 and 32 that, with the apparatus for correcting duty-cycle and phase errors of quadrature signals according to the embodiment of the present disclosure, the accuracy of the phase and duty cycle correction of the quadrature signal can be secured since a phase average and variance of the 8 GHz quadrature signal are simulated as 0.4 deg and 1.5 deg², respectively, and a duty cycle average and variance of the 8 GHz quadrature signal are simulated as 0.8 deg and 1.6 deg², respectively.

FIG. 33 is a diagram illustrating a design layout of the apparatus for correcting duty-cycle and phase errors of quadrature signals according to the embodiment of the present disclosure. In FIG. 33, NANDs+LPF represents the quadrature signal error detector, an IQ error amplifier represents the quadrature error amplifier of the quadrature signal error compensator, duty cycle error amplifiers represent duty cycle error amplifiers of the quadrature signal error compensator, and VCDLs represent voltage controlled delay lines of the quadrature signal error compensator. A total area of the apparatus for correcting duty-cycle and phase errors of quadrature signals according to the embodiment of the present disclosure is 0.00113 mm², power consumption in parts other than the voltage controlled delay line was measured to be 110 uW, and the power efficiency was measured to be 0.1375 mW/GHz.

TABLE 1

| | ISSCC'20 | TCASII'17 | TVLSI'19 | ESSCIRC'21 | JSSC'21 | ISSCC'23 | This work |
|---|---|---|---|---|---|---|---|
| Technology (nm) | 40 | 65 | 55 | 28 | 28 | 40 | 28 |
| Architecture | Digital- | Digital- | Digital- | Digital- | Digital- | Digital- | Analog |
| | DLL QEC | DLL QEC | DLL QEC | DLL QEC | DLL QCG | PLL QCG | QDCC |
| Duty Correction | No | No | No | No | No | No | Yes |
| Frequency Range | 0.8-2.3 | 1.25 | 1.0-3.0 | 0.8-3.2 | 1.3-4.0 | 1.0-4.0 | 1.0-16.0 |
| (GHz) | | | | | | | |
| Quadrature Error | <2.18° | <0.48° | <1.11° | <1.84° | <2.82° | <0.5° | <0.3º |
| Power | 8.9 mW@ | 2.3 mW@ | 2.1 mW@ | 9.8 mW@ | 6.5 mW@ | 0.9 mW@ | 0.11 mW@ |
| Consumption @ | 2.3 GHz | 1.25 GHz | 3.0 GHz | 3.2 GHz | 4.0 GHz | 2.0 GHz | 8 GHz |
| f_{QCLK} | | | | | | | |
| Power Efficiency | 3.87 mW/ | 1.82 mW/ | 0.69 mW/ | 3.06 mW/ | 1.63 mW/ | 0.45 mW/ | 0.14 mW/ |
| | GHz | GHz | GHz | GHz | GHz | GHz | GHz |
| Active Area (mm²) | 0.012 | 0.004 | 0.003 | 0.010 | 0.004 | 0.011 | 0.0011 |

Table 1 shows duty cycle correction function, frequency range, quadrature error, power consumption, power efficiency, and active area characteristics of the apparatus for correcting duty-cycle and phase errors of quadrature signals (This work) according to the embodiment of the present disclosure compared with the related art (ISSCC'20, TCASII'17, TVLSI'19, ESSCIRC'21, JSSC'21, and ISSCC'23).

According to the embodiment of the present disclosure, it is possible to correct the phases and duty cycles of the quadrature signals with high accuracy, and to correct the phases and duty cycles of the quadrature signals in a wide band including a high operating frequency. Further, it can be seen that the embodiment of the present disclosure exhibits the best power efficiency performance and small area/low efficiency performance, and exhibits the highest level of performance in all aspects such as accuracy, background operability, area, power, and frequency band characteristics, compared to the related art.

At least some of the configurations of the embodiments described above can be implemented as hardware components, software components, and/or a combination of the hardware components and the software components. For example, the devices, methods, and components described in the embodiments can be implemented using, for example, one or more general-purpose computers or special-purpose computers, such as a processor, a controller, an arithmetic logic unit (ALU), a digital signal processor, a microcomputer, a field programmable gate array (FPGA), a programmable logic unit (PLU), a microprocessor, or any other device capable of executing and responding to instructions.

A processing device can execute an operating system, and one or more software applications that are executed on the operating system. In addition, the processing device may access, store, manipulate, process, and generate data in response to the execution of the software. For ease of understanding, the processing device is sometimes described as being used alone, but it will be understood by those skilled in the art that the processing device may include a plurality of processing elements and/or a plurality of types of processing elements.

For example, the processing device may include a plurality of processors, or one processor and one controller. Other processing configurations, such as a parallel processor, are also possible. Software may include a computer program, code, instructions, or a combination of one or more of these, and may configure the processing device to operate as desired or may independently or collectively instruct the processing device.

Software and/or data may be embodied in any type of machine, component, physical device, virtual equipment, computer storage medium, or device, for interpretation in the processing device or for provision of instructions or data to the processing device. The software may be distributed over networked computer systems and stored or executed in a distributed manner. The software and data may be stored on one or more computer-readable recording media.

The method according to the embodiment may be implemented in the form of program instructions that can be executed through various computer means and recorded on a computer-readable medium. The computer-readable medium may include program instructions, data files, data structures, or the like alone or in combination. The program instructions recorded on the medium may be those specially designed and configured for the embodiment or may be those known and available to those skilled in the art of computer software.

Examples of computer-readable recording media include a magnetic medium such as a hard disk, floppy disk, and magnetic tape, an optical medium such as a CD-ROM and a DVD, and a hardware device specially configured to store and execute program instructions, such as a ROM, a RAM, and a flash memory. Examples of the program instructions include not only machine language codes such as those created by a compiler, but also high-level language codes that can be executed using an interpreter or the like by a computer. The hardware device may be configured to operate as one or more software modules to perform the operations of the embodiment, and vice versa.

Although the embodiments of the present disclosure have been described with reference to the accompanying drawings, it will be understood by those skilled in the art that the present disclosure may be implemented in other specific forms without departing from the technical spirit or essential features thereof. Therefore, the above-described embodiments should be understood as illustrative and not restrictive in all respects, and the scope of the present disclosure is indicated by the claims to be described below, and all changes or modifications derived from the meaning and scope of the claims and their equivalent concepts should be construed as being included in the scope of the present disclosure.

### DETAILED DESCRIPTION OF MAIN ELEMENTS

10: Apparatus for correcting duty-cycle and phase errors of quadrature signals
100: Quadrature signal error detector
111: First NAND operator
112: Second NAND operator
113: Third NAND operator
114: Fourth NAND operator
120: Low pass filter unit
121: Low pass filter
122: Low pass filter
123: Low pass filter
124: Low pass filter
200: Quadrature signal error compensator
210: Error amplifier
211: Phase error amplification unit
212: Phase error amplifier
213: Phase error low pass filter
214: First bias error amplification unit
215: First bias error amplifier
216: First bias error low pass filter unit
217: Second bias error amplification unit
218: Second bias error amplifier
219: Second bias error low pass filter unit
220: Duty controller
221: First duty cycle adjuster
222: Second duty cycle adjuster
230: Phase adjuster
231: First voltage controlled delay line
232: Second voltage controlled delay line
I_{P}, I_{N}, Q_{P}, Q_{N}: Quadrature signal
I_{PY}, I_{NY}, Q_{PY}, Q_{NY}: Corrected quadrature signal
V_{A}, V_{B}, V_{C}, V_{D}: Error detection signal
V_{CI}, V_{CQ}: I/Q phase error compensation signal
V_{BIP}, V_{BQP}, V_{BIN}, V_{BQN}: Duty cycle error compensation signal

What is claimed is:

1. An apparatus for correcting duty-cycle and phase errors of quadrature signals, comprising:
a quadrature signal error detector configured to detect errors related to duty-cycles and phases of quadrature signals including an I signal, which is an in-phase signal, and a Q signal, which is a quadrature phase signal; and
a quadrature signal error compensator configured to compensate for the duty cycles and phases of the quadrature signals depending on the errors of the quadrature signals, wherein
the quadrature signal error detector is configured to perform a NAND operation or an AND operation on the quadrature signals to detect the errors of the quadrature signals.

2. The apparatus for correcting duty-cycle and phase errors of quadrature signals of claim 1, wherein the quadrature signal error detector includes
a plurality of NAND operators configured to perform a NAND operation on an I signal, a Q signal, an inverted signal of the I signal, and an inverted signal of the Q signal; and
a low pass filter unit configured to perform low pass filtering on output signals of the plurality of NAND operators and output error detection signals.

3. The apparatus for correcting duty-cycle and phase errors of quadrature signals of claim 2, wherein the quadrature signal error compensator includes an error amplifier configured to generate at least one of a phase error compensation signal for amplifying an error of the error detection signals with respect to a reference signal and adjusting a time delay of the quadrature signals and a duty cycle error compensation signal for adjusting bias voltages of the quadrature signals.

4. The apparatus for correcting duty-cycle and phase errors of quadrature signals of claim 3, wherein the quadrature signal error compensator is configured to adjust at least one of a delay time and a bias voltage of the quadrature signals depending on at least one of the phase error compensation signal and the duty cycle error compensation signal.

5. The apparatus for correcting duty-cycle and phase errors of quadrature signals of claim 3, wherein the error amplifier includes
a phase error amplification unit configured to amplify the phase error of the quadrature signals based on the error detection signals of the quadrature signals; and
a bias error amplification unit configured to amplify a bias error of the quadrature signals based on the error detection signals of the quadrature signals.

6. The apparatus for correcting duty-cycle and phase errors of quadrature signals of claim 5, wherein a frequency bandwidth of the phase error amplification unit is set to be higher than that of the bias error amplification unit.

7. The apparatus for correcting duty-cycle and phase errors of quadrature signals of claim 5, wherein the phase error amplification unit includes
a phase error amplifier configured to amplify a phase error of at least two of the error detection signals with respect to the reference signal to generate phase error amplification signals for the I signal and the Q signal; and
a phase error low pass filter unit configured to generate phase error compensation signals for adjusting phases of the quadrature signals by performing low passing on the phase error amplification signals.

8. The apparatus for correcting duty-cycle and phase errors of quadrature signals of claim 5, wherein the bias error amplification unit includes
a bias error amplifier configured to amplify bias errors for at least two of the error detection signals with respect to the reference signal to generate bias error amplification signals for the I signal and the Q signal; and
a bias error low pass filter unit configured to generate duty cycle error compensation signals for adjusting bias voltages of quadrature signals by performing low passing on the bias error amplification signals.

9. The apparatus for correcting duty-cycle and phase errors of quadrature signals of claim 2, wherein the quadrature signal error compensator includes
a phase adjuster configured to adjust phases of the quadrature signals depending on an error of the error detection signals with respect to a reference signal; and
a duty cycle adjuster configured to adjust a bias voltage of the quadrature signals depending on an error of the error detection signals with respect to the reference signal.

10. The apparatus for correcting duty-cycle and phase errors of quadrature signals of claim 1, wherein the quadrature signal error detector includes
a first NAND operator configured to perform a NAND operation on the I signal and the Q signal;
a second NAND operator configured to perform a NAND operation on the I signal and an inverted Q signal that is an inverted signal of the Q signal;
a third NAND operator configured to perform a NAND operation on an inverted I signal which is an inverted signal of the I signal, and the Q signal; and
a fourth NAND operator configured to perform a NAND operation on the inverted I signal and the inverted Q signal.

11. A method for correcting duty-cycle and phase errors of quadrature signals, comprising:
detecting, by a quadrature signal error detector, errors of quadrature signals including an I signal, which is an in-phase signal, and a Q signal, which is a quadrature phase signal; and
compensating for, by a quadrature signal error compensator, duty cycles and phases of the quadrature signals depending on the errors of the quadrature signals, wherein
the detecting of the errors of the quadrature signals includes performing a NAND operation or an AND operation on the quadrature signals to detect the errors of the quadrature signals.

12. A computer-readable non-transitory recording medium having recorded thereon a computer program for executing the method of correcting duty-cycle and phase errors of quadrature signals of claim 11.
